(19) United States
(12) Patent Application Publication
(10) Pub. No.: US 2020/0402882 A1
(43) Pub. Date: Dec. 24, 2020

(54) SEMICONDUCTOR PACKAGE

(71) Applicant: SAMSUNG ELECTRONICS CO., LTD., Suwon-si (KR)

(72) Inventors: Sangwon KIM, Suwon-si (KR); Heejeong Kim, Suwon-si (KR); Unbyoung Kang, Suwon-si (KR); Jongho Lee, Suwon-si (KR)

(73) Assignee: SAMSUNG ELECTRONICS CO., LTD., Suwon-si (KR)

(21) Appl. No.: 16/692,694

(22) Filed: Nov. 22, 2019

(30) Foreign Application Priority Data
Jun. 21, 2019 (KR) 10-2019-0074043

(51) Int. Cl. H01L 23/367; H01L 23/00

(52) U.S. Cl. CPC H01L 23/367; H01L 24/29; H01L 23/562

(57) ABSTRACT

A semiconductor package includes a substrate, a semiconductor stack disposed on the substrate, and a heat slug covering the semiconductor stack. The heat slug includes a flat plate and sidewalls, and the sidewalls include an outer lower portion, and an inner lower portion recessed upwardly from the outer lower portion to form a cavity. The semiconductor package further includes an adhesive interposed between the substrate and the heat slug, and disposed in the cavity.

### CROSS-REFERENCE TO RELATED APPLICATION

This application claims priority from Korean Patent Application No. 10-2019-0074043, filed on Jun. 21, 2019, in the Korean Intellectual Property Office, the disclosure of which is incorporated herein by reference in its entirety.

### BACKGROUND

### 1. Field

This disclosure relates to a semiconductor package capable of reducing an occurrence rate of appearance defects due to adhesive leakage.

### 2. Description of Related Art

To dissipate excess heat due to the high integration and high performance of semiconductor devices, a heat slug may be included in a package. To solve the warpage problem caused by thinning of semiconductor devices, a stiffener may be attached to a package substrate.

When the heat slug or the stiffener is attached to the package substrate, the adhesive may be applied and then subjected to a high-temperature pressurization process. In this process, the adhesive may flow to the outside, resulting in package appearance defects. Therefore, to improve a total production yield of a semiconductor product, a semiconductor package structure capable of reducing an occurrence rate of appearance defects may be developed.

### SUMMARY

According to embodiments, a semiconductor package includes a substrate, a semiconductor stack disposed on the substrate, and a heat slug covering the semiconductor stack. The heat slug includes a flat plate and sidewalls, and the sidewalls include an outer lower portion, and an inner lower portion recessed upwardly from the outer lower portion to form a cavity. The semiconductor package further includes an adhesive interposed between the substrate and the heat slug, and disposed in the cavity.

A semiconductor package includes a substrate, a semiconductor stack disposed on the substrate, a stiffener surrounding a side surface of the semiconductor stack, an adhesive interposed between the substrate and the stiffener, and a cavity containing the adhesive.

A semiconductor package includes a substrate including a trench disposed in the substrate. The trench has a width in a first range of 900 μm to 1100 μm, and the trench has a depth in a second range of 180 μm to 220 μm. The semiconductor package further includes a semiconductor stack disposed on the substrate, a heat slug covering the semiconductor stack. The heat slug includes a flat plate and sidewalls, and the sidewalls include an outer lower portion, and an inner lower portion recessed upwardly from the outer lower portion to form a cavity. The semiconductor package further includes an adhesive interposed between the substrate and the heat slug, and disposed in the cavity.

### BRIEF DESCRIPTION OF THE DRAWINGS

FIG. 1 is a cross-sectional view of a semiconductor package according to embodiments.

FIG. 2 is a diagram illustrating partially recessed sidewalls of a heat slug of a semiconductor package according to embodiments.

FIGS. 3 and 4 are cross-sectional views of a semiconductor package according to embodiments.

FIGS. 5A and 5B are diagrams illustrating a dam of a semiconductor package according to embodiments.

FIGS. 6, 7, 8, 9, 10, 11A, 11B, 11C and 11D are cross-sectional views of a semiconductor package according to embodiments.

### DETAILED DESCRIPTION OF EMBODIMENTS

Embodiments of a semiconductor package are described herein to form a cavity for containing an adhesive on a heat slug or a stiffener, or to include a dam or a trench on a package substrate, to induce the adhesive to flow into the semiconductor package, thereby suppressing leakage to the outside and reducing an occurrence rate of appearance defects of the semiconductor package.

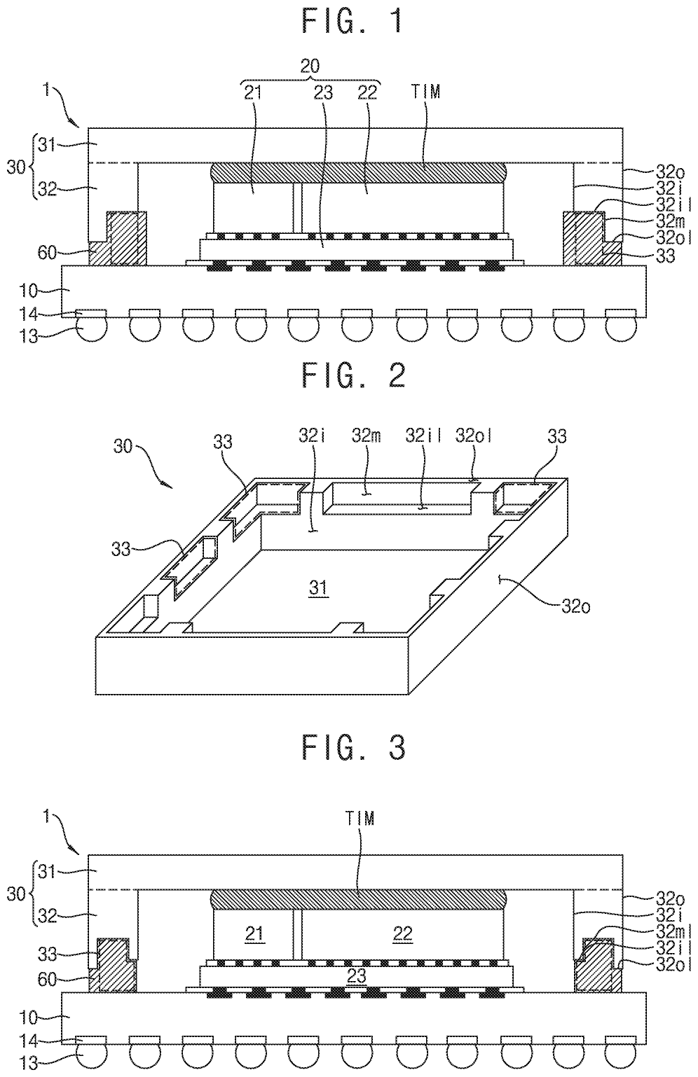

FIG. 1 is a cross-sectional view of a semiconductor package 1 according to embodiments. Referring to FIG. 1, the semiconductor package 1 may include a substrate 10, a semiconductor stack 20, a heat slug 30, and an adhesive 60. The semiconductor package 1 may further include a thermal interface material (TIM) between the semiconductor stack 20 and the heat slug 30.

A semiconductor stack 20 in which semiconductor chips 21, 22, and 23 are stacked can be mounted on a substrate 10. The substrate 10 connects the semiconductor chips 21, 22 and 23 to an external circuit, and can protect and support the semiconductor chips 21, 22 and 23 from external impacts. For example, the substrate 10 may include a printed circuit board (PCB). Referring to FIG. 1, the semiconductor stack 20 may be mounted on a central portion of the substrate 10, and the heat slug 30 may be attached along a periphery of the substrate 10. The substrate 10 may include an upper surface and a lower surface. The upper surface of the substrate 10 is the surface on which the semiconductor stack 20 is mounted. The lower surface of the substrate 10 may be defined as the opposite surface of the upper surface. Bumps 13, such as solder balls, and bump lands 14, may be disposed on the lower surface of the substrate 10.

The semiconductor stack 20 is mounted on the substrate 10, and may be a 2.5D silicon interposer device including a memory chip 21, a logic chip 22, and a silicon interposer 23. In FIGS. 1, 3 to 10 and 11A to 11D of this disclosure, the 2.5D silicon interposer device in which the memory chip 21 and the logic chip 22 are stacked side by side on the silicon interposer 23 is illustrated as the semiconductor stack 20, but the semiconductor stack 20 is not limited thereto, and may be any type of semiconductor requiring packaging, such as a single semiconductor chip, a 2.1D semiconductor device, or a 3D semiconductor device.

The heat slug 30 may cover the semiconductor stack 20 mounted on the substrate 10. Referring to FIG. 1, the heat slug 30 may include a plate 31 that covers the upper portion of the semiconductor stack 20, and sidewalls 32 that surround the side surfaces of the semiconductor stack 20. The heat slug 30 is configured to dissipate excessive heat due to high integration and high performance of the semiconductor stack 20. The heat slug 30 may be made of copper or a copper alloy having a high thermal conductivity as a base material, but is not limited thereto. The heat slug 30 may be attached on the substrate 10 through the adhesive 60.

The plate 31 forms the exterior of the semiconductor package, and can contact the upper portion of the semiconductor stack 20 via the TIM. The plate 31 can quickly dissipate and emit heat emitted from the semiconductor stack 20.

The sidewalls 32 can support the plate 31, and form an exterior of the semiconductor package as one with the plate 31. The sidewalls 32 may include an outer lower portion 32o1 that protrudes relatively downwardly, and an inner lower portion 32i1 that is recessed relatively upwardly. The horizontal width of the outer lower portion 32o1 of the sidewalls 32 may be smaller than the horizontal width of the sidewall 32. Thus, a cavity 33 defined by the recessed inner lower portion 32i1, a middle sidewall portion 32m, and the upper surface of the substrate 10, and open in the package interior direction, can be defined. The adhesive 60 can be contained in the cavity 33. In the case of the semiconductor package 1 including the heat slug 30, the inside of the package is not apparently observed, so that even if the adhesive 60 flows inwardly, the appearance defect does not occur. Thus, the cavity 33 in which the adhesive 60 can be contained, defined on the lower portion of the sidewalls 32 of the heat slug 30, can be opened inwardly of the package.

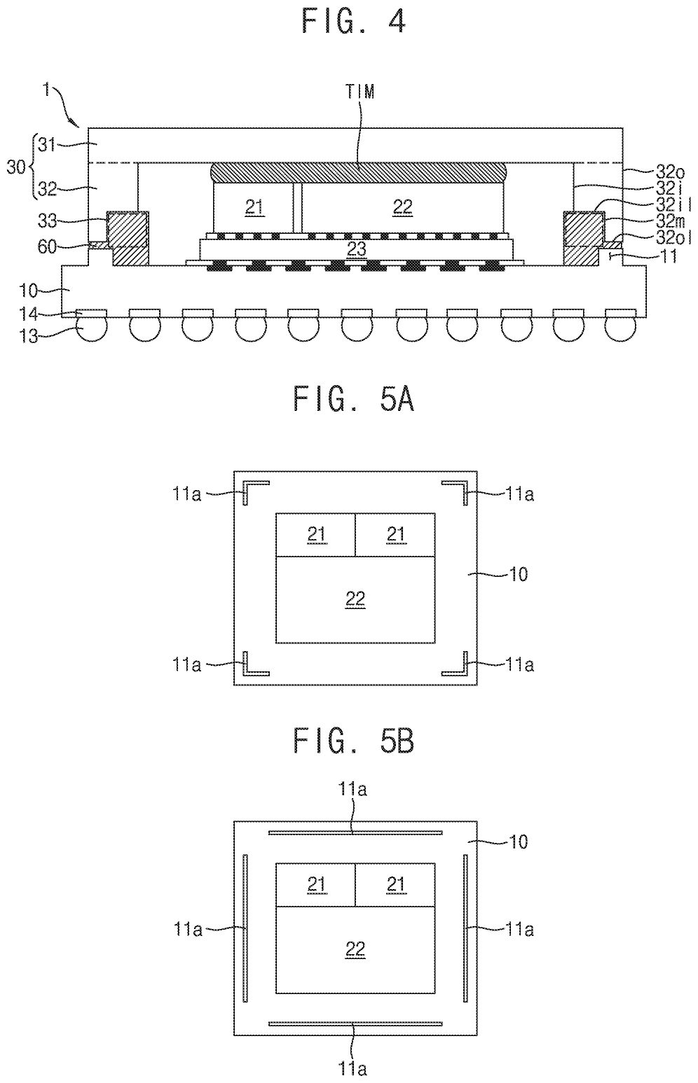

FIG. 2 is a diagram illustrating the partially recessed sidewalls 32 of the heat slug 30 of the semiconductor package 1 according to embodiments. Referring to FIG. 2, the lower portion of the sidewalls 32 may include a plurality of inner lower portions 32i1 partially recessed to form the plurality of cavities 33. In this case, as the total area contacting with the adhesive 60 is increased, the adhesion between the substrate 10 and the heat slug 30 may increase.

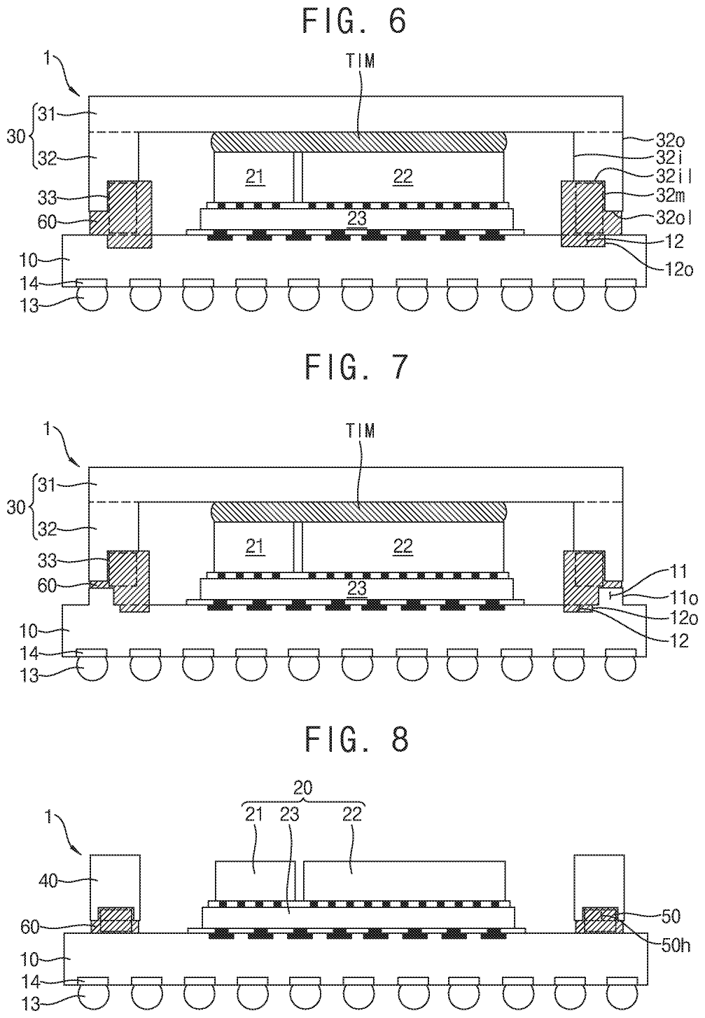

FIGS. 3 and 4 are cross-sectional views of the semiconductor package 1 according to embodiments. Referring to FIG. 3, the sidewall 32 may include the outer lower portion 32o1, the inner lower portion 32i1, and a middle lower portion 32m1. The inner lower portion 32i1 can be recessed upwardly relative to the outer lower portion 32o1. Or the outer lower portion 32o1 may protrude downwardly relative to the inner lower portion 32i1. The middle lower portion 32m1 is disposed between the outer lower portion 32o1 and the inner lower portion 32i1, and can be further recessed upwardly than the inner lower portion 32i1. Thus, the outer lower portion 32o1, the inner lower portion 32i1, and the middle lower portion 32m1 can define the recessed cavity 33. An inner surface 32i may be shorter in vertical length than an outer surface 32o, so that the cavity 33 in which the adhesive 60 can be contained can be opened inwardly of the package.

Referring to FIG. 4, the substrate 10 may include a dam 11 protruding upwardly. The dam 11 is formed on the substrate 10 outside the portion to which the adhesive 60 is applied, to physically prevent the adhesive 60 between the substrate 10 and the heat slug 30 from leaking out of the package. The material of the dam 11 may include a solder resist material, an insulation material, a polymer, a metal, or other suitable barrier material. The dam 11 may be formed by a screen printing method, an electrolytic plating method, an electro-less plating method, a spray coating method, or a deposition process suitable for a material. The dam 11 may be integrally formed with the substrate 10, or may be separately manufactured and attached to the substrate 10.

The dam 11 may have a greater horizontal width than the outer lower portion 32o1 of the sidewall 32 of the heat slug 30. The outer surface 110 of the dam 11 and the outer surface 32o of the sidewall 32 of the heat slug 30 may be co-planar and vertically aligned.

The dam 11 may include a plurality of dam units 11a.

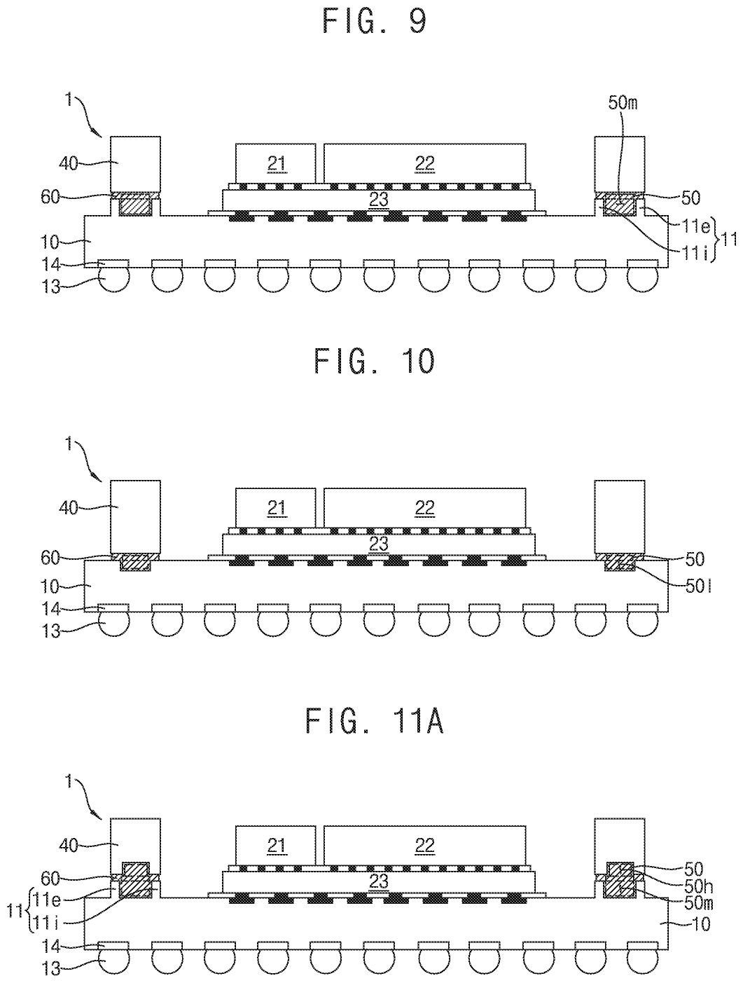

FIGS. 5A and 5B are diagrams illustrating the dam 11 of the semiconductor package 1 according to embodiments. Referring to FIG. 5A, the plurality of dam units 11a may have an elbow-shape, and may be formed on the corner portion of the substrate 10. Referring to FIG. 5B, the plurality of dam units 11a may have a bar-shape or a line-shape, and may be formed to be adjacent to the sides of the substrate 10. The dam 11 of the semiconductor package 1 may be of any type that prevents the adhesive 60 between the substrate 10 and the heat slug 30 from leaking out of the package, and is not limited to the types illustrated in FIG. 5A or 5B.

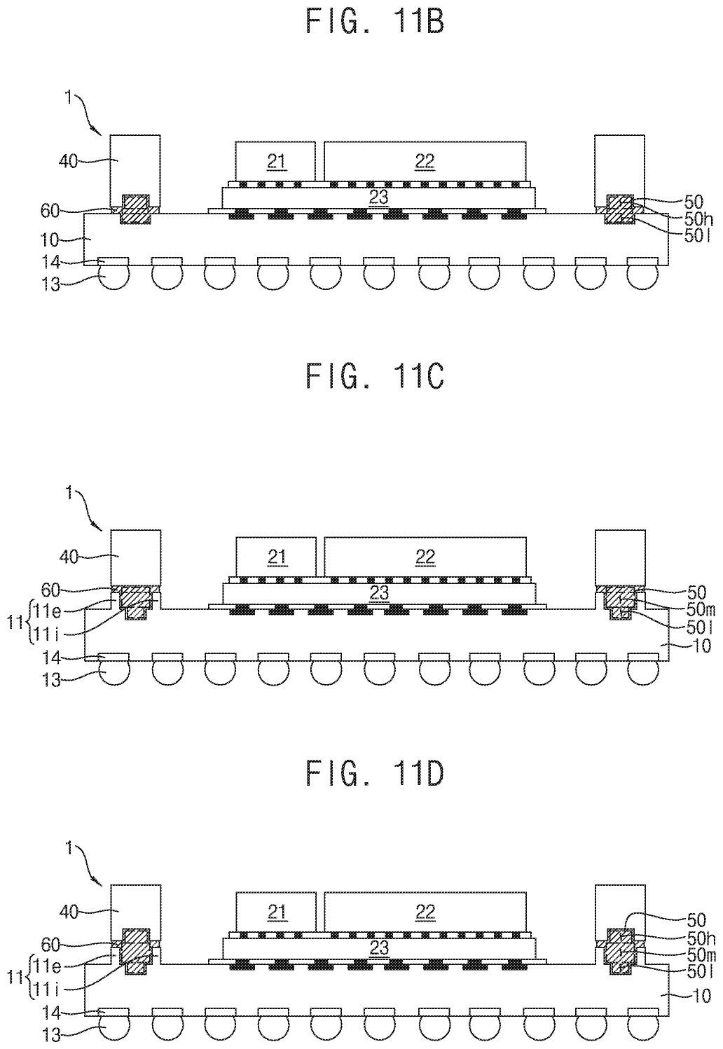

FIGS. 6, 7, 8, 9, 10, 11A, 11B, 11C and 11D are cross-sectional views of a semiconductor package according to embodiments.

Referring to FIG. 6, the substrate 10 may include a downwardly recessed trench 12. The trench 12 is formed on the substrate 10 radially inwardly in the direction towards the semiconductor stack 20 than the portion where the adhesive 60 is provided, guiding the adhesive 60 to flow inside, not the outside of the package, during the high temperature and high pressure process of the semiconductor packaging process. The trenches 12 may be formed parallel to the edge of the substrate 10. The trenches 12 may be connected together or may be separated into a plurality. The trench 12 may be formed at a portion where the sidewall 32 of the heat slug 30 is attached to the substrate 10.

The trench 12 may have a greater horizontal width than the inner lower portion 32i1 of the sidewall 32 of the heat slug 30, and an outer surface 12o of the trench 12 and the middle sidewall portion 32m of the heat slug 30 may be vertically aligned and co-planar. In case of the outer surface 12o of the trench 12 and the middle sidewall portion 32m of the heat slug 30 are vertically aligned, the outer surface of the cavity 33 formed in the lower portion of the heat slug 30, and the outer surface of the trench 12 formed in the substrate 10, are on the same planar vertically, so that the direction in which the adhesive 60 flows is constant and so that leakage of the adhesive 60 can be prevented more effectively. The trench 12 prevents the adhesive 60 from leaking to the outside of the semiconductor package 1. Thus, the outer surface 12o of the trench 12 may be disposed anywhere between the vertically extending surface of the inner surface 32i and the vertically extending surface of the outer surface 32o, not limited to being vertically aligned to the middle sidewall portion 32m of the heat slug 30.

The trench 12 may have a width of 900 nm to 1100 nm in a range not touching the semiconductor stack 20, not to cause damage to the circuit. Further, it may have a depth of 180 μm to 220 μm in a range not exceeding the thickness of the substrate 10. The depth of the trench 12 may be less than the vertical distance from the upper surface of the substrate 10 to the portion where the wiring layer in the substrate 10 is located. That is, the depth of the trench 12 may be smaller than the thickness of the insulating layer covering the wiring layer of the substrate 10. According to embodiments, the substrate 10 may be square in shape with a side length of 42.5 mm in a top-view, and the width of the trench 12 may be 1000 μm and the depth may be 200 μm.

Referring to FIG. 7, the substrate 10 may include the dam 11 protruding upwardly and the trench 12 recessed downwardly. In this case, leakage of the adhesive 60 can be prevented in a redundant manner through the cavity 33 formed in the heat slug 30, the dam 11, and the trench 12, so that the occurrence rate of appearance defects of the semiconductor package 1 can be more effectively reduced. The cavity 33 formed on the lower portion of the heat slug 30, and the dam 11 and the trench 12 of the substrate 10, can be partially overlapped. The portion where the lower portion of the heat slug 30 is recessed and the portion where the substrate 10 is recessed to form the trench 12 may not be vertically aligned with each other. In addition, the dam 11 may not always be formed at the outer edge of the portion where the trench 12 is formed. As described above, the semiconductor package 1 may include the cavities of the heat slug 30, the dam 11 and the trench 12 of the substrate 10 in a redundant manner at the portion where the leakage of the adhesive 60 occur well, and may include only one or none of the types at the portion where the leakage of the adhesive 60 does not occur well. Any one or any combination of the cavity 33 of the heat slug 30, the dam 11 and the trench 12 of the substrate 10, is partially included on the edge of the semiconductor package 1 as necessary, to effectively prevent leakage of the adhesive 60.

FIGS. 8 to 10 and FIGS. 11A to 11D show various embodiments including a stiffener 40. Referring to FIG. 8, the semiconductor package 1 may include the substrate 10, the semiconductor stack 20, the stiffener 40, a cavity 50, and the adhesive 60.

The stiffener 40 may be in the form of a frame surrounding the sides of the semiconductor stack 20 mounted on the substrate 10 in a top-view. The stiffener 40 is a structure for solving the package warpage problem due to the thinning and miniaturizing of the semiconductor stack 20. If the degree of package warpage is large, the solder joint may cause a non-wetting-defect due to disconnection to the substrate, or may cause a short-defect due to melting of adjacent solder balls. By attaching the frame-shaped stiffener 40 along the outer periphery of the substrate 10, it is possible to increase rigidity of the substrate 10 and prevent it from being deformed by an external force.

The cavity 50 is a space capable of containing the adhesive 60 between the stiffener 40 and the substrate 10. In the case of the semiconductor package 1 including the stiffener 40, not only the outer side of the substrate 10 but also the inner region of the stiffener 40, that is, the region of the substrate 10 on which the semiconductor stack 20 is mounted, are exposed to be able to observe. Therefore, unlike the case of the semiconductor package 1 including the heat slug 30, the adhesive 60 flowing into the inner region of the stiffener 40, also causes appearance defect of the package. In the semiconductor package 1, the cavity 50 may have a horizontal width smaller than that of the stiffener 40 to reduce the occurrence rate of appearance defects.

The cavity 50 having a smaller horizontal width than the stiffener 40 can be formed in a region where the stiffener 40 is attached to the substrate 10. In this case, the cavity 50 is not visible in the top-view, and exposure of the adhesive 60 contained in the cavity 50 is prevented, thereby reducing the occurrence rate of appearance defects.

FIGS. 8, 9, 10, 11A, 11B, 11C and 11D illustrate states in which the adhesive 60 is contained in the cavity 50 without any void, but according to embodiments, the cavity 50 may include an empty space, such as a bubble. To prevent the adhesive 60 from leaking out of the stiffener 40, the total sum of the capacities of the cavities 50 may be larger than the total amount of the adhesives 60 used. Further, to secure a space for allowing the adhesive 60 to flow into the cavity 50, the cavity 50 may include as much empty space not containing the adhesive 60 as.

The pressure inside the cavity 50 may be smaller than the atmospheric pressure outside the package to more effectively prevent the external leakage of the adhesive 60, i.e., to more effectively cause the adhesive 60 to flow into the cavity 50. To prevent the resistance of flowing of the adhesive 60 into the cavity 50 due to the pressure inside the cavity 50, the cavity 50 may include an air hole for maintaining the pressure.

Referring to FIG. 8, the cavity 50 may include an upper portion 50h formed by upwardly recessing the lower surface of the stiffener 40. The lower surface of the stiffener 40 may be a surface directly contacting the adhesive 60 when the stiffener 40 is attached to the substrate 10. By forming the cavity 50 in the stiffener 40, it is possible to induce the adhesive 60 to flow into the cavity 50 that is not visible from the outside, when the external force is applied. The upper portion 50h of the cavity 50 may be connected together or may include a plurality of discrete portions.

Referring to FIG. 9, the substrate 10 may include the dam 11 protruding upwardly, and the cavity 50 may include an intermediate portion 50m formed by the dam 11. The dam 11 may include an inner portion 11i and an outer portion 11e. To prevent the adhesive 60 from leaking into and out of the stiffener 40 in the semiconductor package 1 including the stiffener 40, the inner portion 11i may be disposed on the inner side of the cavity 50, and the outer portion 11e may be disposed on the outer side of the cavity 50. The total sum of the width of the inner portion 11i, the width of the intermediate portion 50m of the cavity 50, and the width of the outer portion 11e may be smaller or equal than the width of the stiffener 40, to prevent the leakage of the adhesive 60 effectively.

The dam 11 may include the plurality of separated dam units 11a according to embodiments. Each of the inner portion 11i and the outer portion 11e may include the plurality of separated dam units 11a. The dam units 11a may have an elbow-shape disposed on the corner portion of the substrate 10, or may have a bar-shape or a line-shape arranged to be adjacent to the sides of the substrate 10.

Referring to FIG. 10, the cavity 50 may include a lower portion 50l formed by downwardly recessing the substrate 10. The lower portion 50l of the cavity 50 may be formed along the edge of the substrate 10 at a portion where the stiffener 40 is attached to the substrate 10. The lower portion 50l of the cavity 50 may be connected together, or may be separated into a plurality of cavities.

FIGS. 11A to 11D are cross-sectional views of embodiments in which includes at least two kinds of an upper portion 50h cavity formed by upwardly recessing the lower surface 401 of the stiffener 40, the intermediate portion 50m cavity formed by the dam 11 protruding upwardly from the substrate 10, and the lower portion 50l cavity formed by downwardly recessing the substrate 10.

Referring to FIG. 11A, the cavity 50 includes the upper portion 50h formed by upwardly recessing the lower surface 401 of the stiffener 40. The substrate 10 includes the dam 11 protruding upwardly, and the cavity 50 may further include the intermediate portion 50m formed by the dam 11. Referring to FIG. 11A, the width of the upper portion 50h of the cavity 50 and the width of the intermediate portion 50m of the cavity 50 may be different from each other.

Referring to FIG. 11B, the cavity 50 may include the upper portion 50h formed by upwardly recessing the lower surface 401 of the stiffener 40, and the lower portion 50l formed by downwardly recessing the substrate 10. Referring to FIG. 11B, the width of the upper portion 50h of the cavity 50 and the width of the lower portion 50l of the cavity 50 may be different from each other. The width of the lower portion 50l of the cavity 50 may be smaller than the width of the stiffener 40 so that the stiffener 40 can be easily attached to the substrate 10.

Referring to FIG. 11C, the cavity 50 may include the intermediate portion 50m formed by the dam 11 protruding upwardly from the substrate 10, and the lower portion 50l formed by downwardly recessing the substrate 10. Referring to FIG. 11C, the width of the intermediate portion 50m of the cavity 50 and the width of the lower portion 50l of the cavity 50 may be different from each other. The cavity 50 may be configured in a step-type in which the width of the lower portion 50l of the cavity 50 is smaller than the width of the intermediate portion 50m of the cavity, to more effectively guide the adhesive 60 to flow into the cavity 50. When the cavity 50 is formed in a step-type, the direction of the flow of the adhesive 60 is kept constant, so that the adhesive 60 can easily flow as compared with the case of the reverse-step-type.

Referring to FIG. 11D, the cavity 50 may include all kinds of the upper portion 50h cavity formed by upwardly recessing the lower surface 401 of the stiffener 40, the intermediate portion 50m cavity formed by the dam 11 protruding upwardly from the substrate 10, and the lower portion 50l cavity formed by downwardly recessing the substrate 10. However, the upper portion 50h cavity, the intermediate portion 50m cavity, and the lower portion 50l cavity may not all be included in a location. The cavity 50 may include more than two kinds of the upper portion 50h, the intermediate portion 50m, and the lower portion 50l in a redundant manner at the portion where the leakage of the adhesive 60 occur well, and the cavity 50 may include only one kind or none of the upper portion 50h, the intermediate portion 50m, and the lower portion 50l at the portion where the leakage of the adhesive 60 does not occur well. The upper portion 50h, the intermediate portion 50m, and the lower portion 50l may be partially overlapped with each other as needed to prevent the leakage of the adhesive 60 effectively.

The adhesive 60 can bond the substrate 10 and the heat slug 30 or the substrate 10 and the stiffener 40 to each other. The adhesive 60 applied to the lower portion of the sidewall 32 of the heat slug 30 or the lower portion of the stiffener 40 may be more adhesive to have higher thermal conductivity. Therefore, the component of the adhesive 60 may be a material having a stronger adhesion than a thermal interface material (TIM) that directly contacts the upper portion of the semiconductor stack 20 to transfer the heat to the plate 31 of the heat slug 30. The adhesive 60 of the semiconductor package 1 may include SiO₂ (silicon dioxide, silica) or Al₂O₃(aluminum oxide, alumina).

While the example embodiments have been described with reference to the accompanying drawings, those skilled in the art to which the disclosure pertains can understand that the disclosure may be implemented in other forms without departing from the technical spirit or the features of the disclosure. It may be understood that the above-described example embodiments are not limitative but illustrative in all aspects.

What is claimed is:

1. A semiconductor package, comprising:
a substrate;
a semiconductor stack disposed on the substrate;
a heat slug covering the semiconductor stack,
wherein the heat slug comprises a flat plate and sidewalls, and
wherein the sidewalls comprise an outer lower portion, and an inner lower portion recessed upwardly from the outer lower portion to form a cavity; and
an adhesive interposed between the substrate and the heat slug, and disposed in the cavity.

2. The semiconductor package of claim 1, wherein the sidewalls comprise a plurality of inner lower portions recessed from the outer lower portion to form a plurality of cavities.

3. The semiconductor package of claim 1, wherein the sidewalls further comprise a middle lower portion recessed upwardly from the inner lower portion, and
wherein the middle lower portion is interposed between the outer lower portion and the inner lower portion.

4. The semiconductor package of claim 1, wherein the substrate comprises a dam protruding upwardly from a top surface of the substrate.

5. The semiconductor package of claim 4, wherein a first horizontal width of the dam is greater than a second horizontal width of the outer lower portion of the sidewalls of the heat slug, and
wherein a first outer surface of the dam and a second outer surface of the sidewalls of the heat slug are vertically aligned and co-planar.

6. The semiconductor package of claim 4, wherein the dam comprises a plurality of dam units.

7. The semiconductor package of claim 1, wherein the substrate comprises a trench disposed in the substrate.

8. The semiconductor package of claim 7, wherein a first horizontal width of the trench is greater than a second horizontal width of the inner lower portion of the sidewalls of the heat slug, and
wherein an outer surface of the trench and a middle sidewall portion of the sidewalls of the heat slug are vertically aligned and a co-planar.

9. The semiconductor package of claim 7, wherein the substrate further comprises a dam protruding upwardly from a top surface of the substrate.

10. A semiconductor package, comprising:
a substrate;
a semiconductor stack disposed on the substrate;
a stiffener surrounding a side surface of the semiconductor stack;
an adhesive interposed between the substrate and the stiffener; and
a cavity containing the adhesive.

11. The semiconductor package of claim 10, wherein a first horizontal width of the cavity is less than a second horizontal width of the stiffener.

12. The semiconductor package of claim 10, wherein the cavity comprises an upper portion recessed upwardly from a lower surface of the stiffener.

13. The semiconductor package of claim 12, wherein the substrate comprises a dam protruding upwardly from a top surface of the substrate,
wherein the dam comprises an outer portion and an inner portion, and
wherein the cavity further comprises an intermediate portion formed by the outer portion and the inner portion of the dam.

14. The semiconductor package of claim 13, wherein the dam comprises a plurality of dam units.

15. The semiconductor package of claim 12, wherein the cavity further comprises a lower portion recessed downwardly from a top surface of the substrate.

16. The semiconductor package of claim 10, wherein the substrate comprises a dam protruding upwardly from a top surface of the substrate,
wherein the dam comprises an outer portion and an inner portion, and
wherein the cavity further comprises an intermediate portion formed by the outer portion and the inner portion of the dam.

17. The semiconductor package of claim 16, wherein the dam comprises a plurality of dam units.

18. The semiconductor package of claim 16, wherein the cavity further comprises a lower portion recessed downwardly from the top surface of the substrate.

19. The semiconductor package of claim 10, wherein the cavity comprises a lower portion recessed downwardly from a top surface of the substrate.

20. A semiconductor package, comprising:
a substrate comprising a trench disposed in the substrate,
wherein the trench has a width in a first range of 900 μm to 1100 μm, and
wherein the trench has a depth in a second range of 180 μm to 220 μm;
a semiconductor stack disposed on the substrate;
a heat slug covering the semiconductor stack,
wherein the heat slug comprises a flat plate and sidewalls, and
wherein the sidewalls comprise an outer lower portion, and an inner lower portion recessed upwardly from the outer lower portion to form a cavity; and
an adhesive interposed between the substrate and the heat slug, and disposed in the cavity.
